(19) United States
(12) Patent Application Publication
(10) Pub. No.: US 2011/0078522 A1
(43) Pub. Date: Mar. 31, 2011

(54) SEMICONDUCTOR INTEGRATED CIRCUIT DEVICE

(75) Inventor: Taketoshi SUZUKI, Tokyo (JP)

(73) Assignee: KABUSHIKI KAISHA TOSHIBA, Tokyo (JP)

(21) Appl. No.: 12/895,322

(22) Filed: Sep. 30, 2010

(30) Foreign Application Priority Data
Sep. 30, 2009 (JP) P2009-228926

(51) Int. Cl. G01R 31/28

(52) U.S. Cl. 714/724

(57) ABSTRACT

A self-test circuit includes a test circuit for processing input data and outputting output data having higher randomness than the input data; a storage unit for holding initial input data to be inputted to the test circuit when a self-test operation is performed on the test circuit; a feedback unit for feeding back, as input data to the test circuit, the output data which is obtained through processing of the input data by the test circuit and which is outputted from the test circuit; a control unit for controlling the number of times that the feedback unit feeds back the output data from the test circuit as input data to the test circuit; and a comparing unit for comparing the output data outputted from the test circuit and an expected value.

### CROSS-REFERENCE TO RELATED APPLICATIONS

This Application is based upon and claims the benefit of priority from the prior Japanese Patent Application No. P2009-228926, filed on Sep. 30, 2009; the entire contents of which are incorporated herein by reference.

### BACKGROUND

1. Field

Embodiments described herein relate generally to semiconductor integrated circuit device.

2. Description of Related Art

Among LSI (Large Scale Integration) test methods, scan path testing is most frequently used. In scan path testing, a test circuit is tested as follows: a test vector is inputted from an external LSI tester to the test circuit using scan design, and an output produced in response to the test vector is measured by the LSI tester and compared with an expected value. In scan path testing, the following problems have occurred: an increase in the number of test vectors and test pins due to an increase in the size of LSIs as circuits under test, an increase in tester cost due to high-speed testing, and the like. Further, in scan path testing, data in a test circuit is read out by an LSI tester. Hence, in the case where the test circuit is an encryption circuit or the like, a secret key and the like stored in the encryption circuit may be read out through a scan path.

LSI test methods other than scan path testing include Built-in Self Test (BIST). A semiconductor integrated circuit which carries out a BIST includes a test circuit using scan design and a circuit (self-test circuit) having functions of an LSI tester for testing a test circuit, and can perform a simple test on the test circuit using the self-test circuit (e.g., see Patent Document 1). Thus, the aforementioned problems of scan path testing can be solved with a BIST.

In a BIST, the probability (fault coverage) of detection of a fault in a test circuit by a self-test circuit depends on the randomness of a test pattern. In other words, fault coverage can be improved by using a highly random test pattern. However, in an n-stage LFSR (Linear Feedback Shift Registers) used as a test pattern generating circuit in the self-test circuit, a generated test pattern is generally a pseudo random test pattern with a period of 2ⁿ−1 by the nature of the LFSR. Accordingly, a test pattern needed to detect a fault in the test circuit is not generated in some cases. Moreover, in a semiconductor integrated circuit which carries out a BIST, an LFSR is generally mounted on a chip as a test pattern generating circuit, and thus there is the problem that the circuit size of the chip increases. Moreover, similar to an LSI, a semiconductor integrated circuit which carries out a BIST requires the scan design of a test circuit. Thus, there is the problem that the circuit size is increased by a scan path.

### BRIEF DESCRIPTION OF THE DRAWINGS

FIG. 1 is a block diagram showing a schematic configuration of a test circuit and a self-test circuit included in a semiconductor integrated circuit according to a first embodiment.

FIG. 2 is a block diagram showing a configuration of the test circuit and the self-test circuit included in the semiconductor integrated circuit according to the first embodiment.

FIG. 3 is a view for explaining a Feistel structure, which is one example of an encryption algorithm of a cryptographic core circuit.

FIG. 4 is a circuit showing one example of a storage unit.

FIG. 5 is a timing diagram for the case where a BIST is carried out.

FIG. 6 is a table showing results of performing a BIST on a gate net of the integrated circuit by simulation.

FIG. 7 is a block diagram showing a configuration of a test circuit and a self-test circuit included in a semiconductor integrated circuit according to a second embodiment of the present invention.

### DETAILED DESCRIPTION

Hereinafter, embodiments of the present invention will be described with reference to the drawings.

### First Embodiment

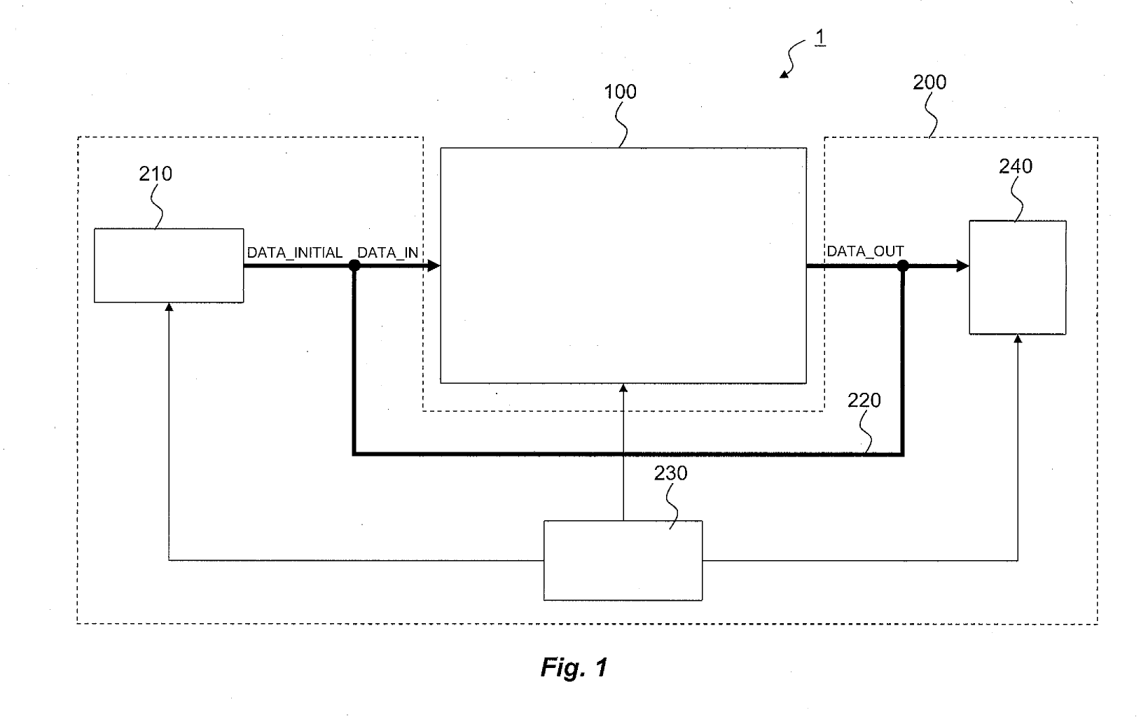

A schematic configuration of a test circuit and a self-test circuit included in a semiconductor integrated circuit of this embodiment will be described with reference to FIG. 1. FIG. 1 is a block diagram showing the schematic configuration of the test circuit and the self-test circuit included in a semiconductor integrated circuit according to a first embodiment of the present invention.

A semiconductor integrated circuit 1 of this embodiment includes a test circuit 100 and a self-test circuit 200 for carrying out a BIST on the test circuit 100. The self-test circuit 200 includes a storage unit 210, a feedback unit 220, a control unit 230, and a comparing unit 240. It should be noted that the semiconductor integrated circuit 1 may include integrated circuits having functions other than those of the test circuit 100 and the self-test circuit 200.

When a BIST is carried out, first, an initial test pattern DATA_INITIAL is inputted as input data DATA_IN from the storage unit 210 to the test circuit 100. Next, the test circuit 100 processes (performs an operation on) the input data DATA_IN (initial test pattern DATA_INITIAL), and outputs output data DATA_OUT having higher randomness than the input data DATA_IN (initial test pattern DATA_INITIAL). Next, the feedback unit 220 feeds back the output data DATA_OUT outputted from the test circuit 100 as input data DATA_IN to the test circuit 100. Next, the test circuit 100 processes (performs an operation on) the input data DATA_IN, and outputs output data DATA_OUT having higher randomness than the input data DATA_IN. Then, similarly, the following operations are repeated: the feedback unit 220 feeds back the output data DATA_OUT outputted from the test circuit 100 as input data DATA_IN to the test circuit 100; and the test circuit 100 processes (performs an operation on) the input data DATA_IN, and outputs output data DATA_OUT having higher randomness than the input data DATA_IN. The control unit 230 controls the number (number of times of feedback) of times that a feedback action is performed. When the number of times of feedback reaches a preset number of times, the comparing unit 240 compares the output data DATA_OUT outputted from the test circuit 100 and an expected value. In the case where this output data and the expected value do not coincide, it is detected that the test circuit 100 has a fault.

As described above, in this embodiment, input data DATA_IN can be made data having high randomness by repeating a feedback action. In a BIST, the probability (fault coverage) of detection of a fault in a test circuit depends on the randomness of data inputted to a test circuit. Accordingly, in this embodiment, fault coverage obtained when a BIST is carried out can be improved. Further, since input data DATA_IN can be made more random by repeating a feedback action, less random simple data can be used as the initial input data DATA_INITIAL. Accordingly, unlike conventional cases, LFSR for generating a pseudo random test pattern does not need to be provided. This can simplify the configuration of the storage unit 210 for storing the initial input data DATA_INITIAL, and can realize a reduction in footprint.

Further, since the initial input data DATA_INITIAL is randomized, the test circuit 100 can be activated when a HIST is carried out, and thus scan design is not required for the test circuit 100. Thus, the circuit size of the test circuit 100 can be reduced.

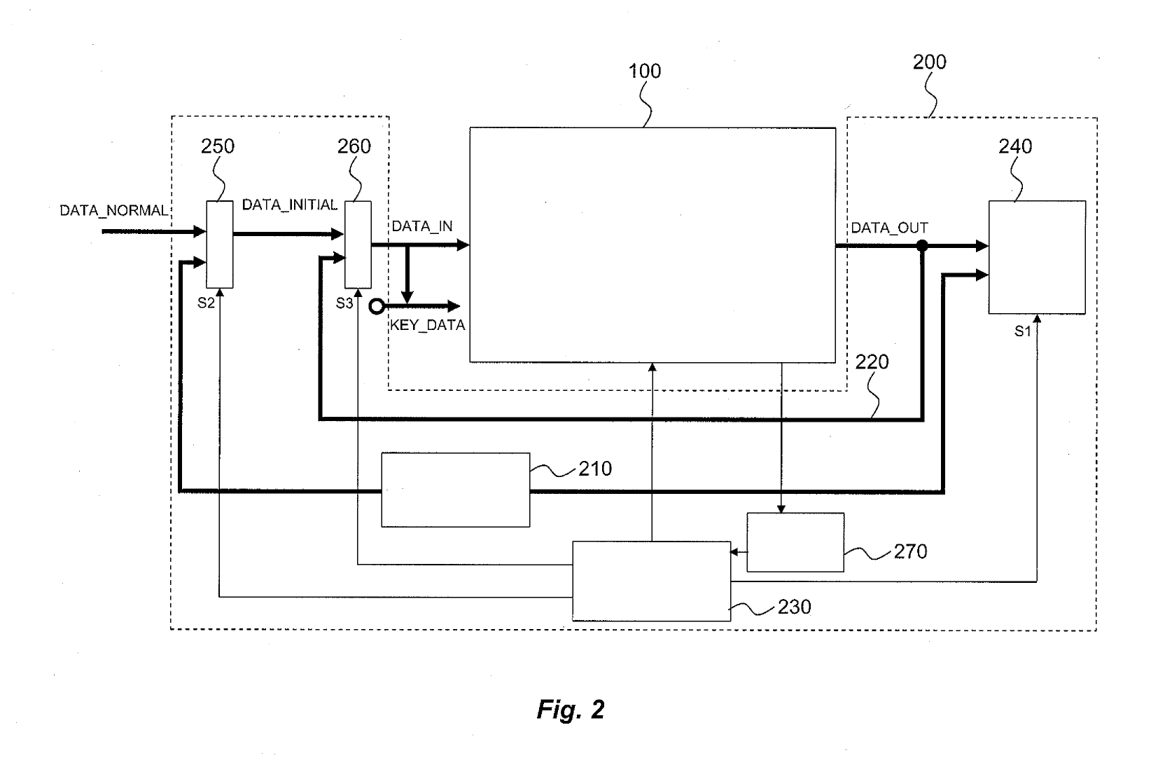

Next, the configuration of the test circuit and the self-test circuit included in the semiconductor integrated circuit of this embodiment will be described in more detail with reference to FIG. 2. FIG. 2 is a block diagram showing the configuration of the test circuit and the self-test circuit included in the semiconductor integrated circuit according to the first embodiment of the present invention. In FIG. 2, components identical or equivalent to those shown in FIG. 1 are denoted by the same reference numerals.

As described previously, the test circuit 100 processes (performs an operation on) input data DATA_IN inputted to the test circuit 100, and outputs output data DATA_OUT having higher randomness than the input data DATA_IN. In FIG. 2, the test circuit 100, which outputs output data DATA_OUT having higher randomness than input data DATA_IN, is assumed to be a cryptographic core circuit. The test circuit (cryptographic core circuit) 100 receives input data DATA_IN and cryptographic key data KEY_DATA. The test circuit (cryptographic core circuit) 100 mixes the input data DATA_IN and the cryptographic key data KEY_DATA, and outputs highly random output data DATA_OUT. How the cryptographic core circuit outputs output data DATA_OUT having higher randomness than input data DATA_IN will be described later.

As described previously, the self-test circuit 200 includes the storage unit 210, the feedback unit 220, the control unit 230, and the comparing unit 240. The self-test circuit 200 also includes multiplexers 250 and 260, and may further include a counter portion 270.

The storage unit 210 stores initial input data (referred to as an “initial test pattern”) DATA_INITIAL to be inputted to the test circuit when a BIST is carried out on the test circuit 100. Moreover, the storage unit 210 stores an expected value EXPECTATION to be referenced to by the comparing unit 240. Furthermore, the storage unit 210 stores the cryptographic key data KEY_DATA to be inputted to the test circuit 100 (cryptographic core circuit). The initial test pattern DATA_INITIAL may be, for example, simple 128-bit all-“0” or all-“1” data. Moreover, it is also possible to double use the initial test pattern DATA_INITIAL as the cryptographic key data KEY_DATA. Accordingly, the storage unit 210 does not need to be a ROM (Read Only Memory) having cells thereof compiled, and may be configured using, for example, a ROM built from combinational circuits, and the like. Thus, the storage unit 210 can be implemented by a circuit which has a small circuit size and which requires a low implementation cost. It should be noted that although in this embodiment, the storage unit 210 collectively stores the initial test pattern and the expected value, two storage units may be provided to store the initial test pattern and the expected value separately from each other.

The feedback unit 220 feeds back the output data DATA_OUT outputted from the test circuit 100 as input data DATA_IN to the test circuit 100. In this embodiment, as one configuration example, the output data DATA_OUT from the test circuit 100 is fed back through the feedback unit 220 to be inputted to the multiplexer 260. The output signal DATA_OUT fed back through the feedback unit 220 is selected by the multiplexer 260 to be inputted to the test circuit 100 as input data DATA_IN. Moreover, the output data DATA_OUT from the test circuit 100 fed back through the feedback unit 220 may also be fed back to a cryptographic key data input of the test circuit 100. In this case, when a BIST is carried out, data to be initially inputted to the cryptographic key data input of the test circuit 100 is inputted from the storage unit 210, and thereafter, the output data DATA_OUT from the test circuit 100 fed back through the feedback unit 220 is inputted to the cryptographic key data input.

The control unit 230 controls the number (number of times of feedback) of times that the feedback unit 220 feeds back the output data DATA_OUT from the test circuit as input data DATA_IN to the test circuit. Moreover, the control unit 230 controls the test circuit 100, the storage unit 210, the comparing unit 240, and the multiplexers 250 and 260.

After the number of times of feedback reaches a predetermined number, the comparing unit 240 compares the output data DATA_OUT outputted from the test circuit 100 and the expected value EXPECTATION stored in the storage unit 210. The comparing unit 240 compares the output data DATA_OUT and the expected value EXPECTATION on the basis of a signal S1 from the control unit 230. Here, the expected value EXPECTATION is data to be outputted from the test circuit 100 in the case where a BIST is performed on a test circuit having no fault.

The multiplexer 250 receives normal data DATA_NORMAL which the test circuit 100 processes (performs an operation on) in normal operation, and the initial test pattern DATA_INITIAL held in the storage unit 210. The multiplexer 250 selects one of the normal data DATA_NORMAL and the initial test pattern DATA_INITIAL on the basis of a signal S2 from the control unit 230, and outputs the selected one to the multiplexer 260. When a BIST is carried out, the multiplexer 250 selects and outputs the initial test pattern DATA_INITIAL to the multiplexer 260.

The multiplexer 260 receives output data DATA_INITIAL from the multiplexer 250 (when a BIST is carried out), and the output data DATA_OUT from the test circuit 100 fed back through the feedback unit 220. The multiplexer 260 selects, on the basis of a signal S3 from the control unit 230, one of the output data DATA_INITIAL from the multiplexer 250 and the output data DATA_OUT from the test circuit 100 fed back through the feedback unit 220 and outputs the selected one as input data DATA_IN to the test circuit 100.

The counter portion 270 counts the number of times of feedback. The control unit 230 controls the number of times of feedback on the basis of the number of times of feedback counted by the counter portion 270.

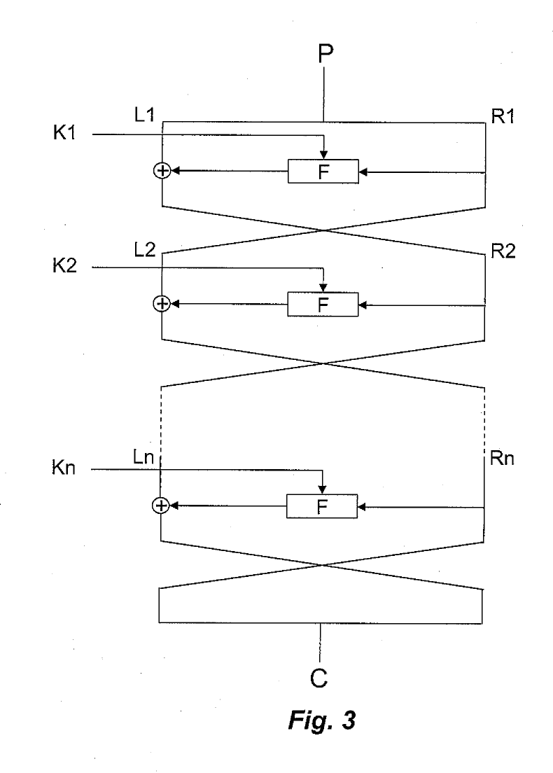

Next, how the test circuit outputs output data having higher randomness than input data will be described with reference to FIG. 3. FIG. 3 is a view for explaining a Feistel structure, which is one example of an encryption algorithm of the cryptographic core circuit.

To a block cipher having a Feistel structure, 64-bit plaintext data P (corresponding to the input data DATA_IN in FIG. 2) is inputted. The plaintext data P is divided into 64-bit block data R1 on the right side and 32-bit block data L1 on the left side. The 64-bit block data R1 on the right side is inputted to an F-function 101 and is converted by the F-function 101. To the F-function 101, a cryptographic key K1 is inputted from outside. The cryptographic key K1 is part of key data (corresponding to the cryptographic key data KEY_DATA in FIG. 2) expanded by key expansion. The conversion of the block data R1 by the F-function 101 includes the following processings: expansion-transposition, exclusive OR operation with a key, S-BOX (Substitution-box), and P-BOX (Premutation-box) transposition. The block data R1 converted by the F-function 101 is outputted as block data F(R1, K1). Next, the block data F(R1, K1) is subjected to an exclusive OR operation with the 32-bit block data R1 on the right side, and block data L1⊕F(R1, K1) is outputted. The above-described processing by which the block data L1⊕F(R1, K1) is calculated from the block data R1 and L1 is one round of processing. Next, the block data L1⊕F(R1, K1) obtained by the processing of the first round is assigned to block data R2, R1 is assigned to L2, and similar processing is repeated. As described above, the Feistel structure is a round function. In the DES, by repeating such a round function for 16 rounds and finally performing inverse transposition, 64-bit ciphertext C is created.

As described above, the test circuit 100, which is a cryptographic core circuit, mixes simple input data (plaintext) by use of a round function according to an encryption algorithm such as a Feistel structure, and outputs highly random output data (ciphertext). Accordingly, as described previously, by repeatedly feeding back output data DATA_OUT from the test circuit 100 (cryptographic core circuit) as input data DATA_IN to the test circuit 100, input data to the test circuit 100 can be made to have high randomness. Further, by repeating feedback, input data to the test circuit 100 can be made to have higher randomness.

Moreover, although in the above description, a Feistel structure has been described as one example of the encryption algorithm of the test circuit 100 (cryptographic core circuit), the encryption algorithm of the test circuit 100 may be other block cipher such as AES having an SPN structure, a hash function-based cryptography, a public key cryptography, and the like. Various encryption algorithms are possible. This is because a cryptographic core circuit generally outputs highly random output data (ciphertext) for simple input data (plaintext).

Furthermore, the test circuit 100 may be, other than a cryptographic core circuit, a data compression core for image/speech compression or the like such as JPEG, MPEG, or MP3, file compression or the like such as ZIP, or the like. This is because a data compression core for image/speech compression or the like implements various data conversion algorithms for decompressing and compressing data, and therefore outputs highly random output data having for simple input data.

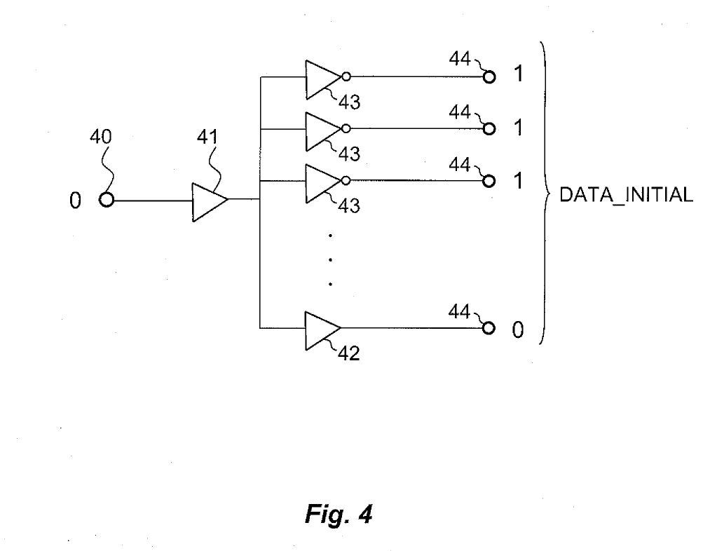

Next, one example of the configuration of the storage unit 210 will be described with reference to FIG. 4. FIG. 4 is a circuit showing one example of the storage unit.

The storage unit 210 includes an address line 40, buffers 41 and 42, inverters 43, and output lines 44. To the address line 40, the multiple inverters 43 and the buffer 42 as well as the output lines 44 are connected through the buffer 41.

Data “0” inputted to the address line 40 is outputted through the buffer 42 and the inverters 43 to the output lines 44. A value outputted from the output lines 44 is data (i.e., the initial input data DATA_INITIAL) outputted from the storage unit 210. In FIG. 4, for a value of “0” applied to the address line 40, data “111 . . . 0” is outputted. In the case where the value applied to the address line 40 is “1,” inverted data “000 . . . 1” is outputted. It should be noted that the outputted data can be changed by changing the combination of buffers 42 and inverters 43. For example, if all the inverters 43 are replaced with buffers, data “000 . . . 0” (all “0”) is outputted for a value of “0” applied to the address line 40. Moreover, the outputted data can also be fixed by employing a configuration in which the address line 40 is pulled up to “1” or down to “0.” It should be noted that even in the case of an address containing two or more bits, a ROM built from combinational circuits is represented by the combination of buffers 42 and inverters 43 in accordance with the output values.

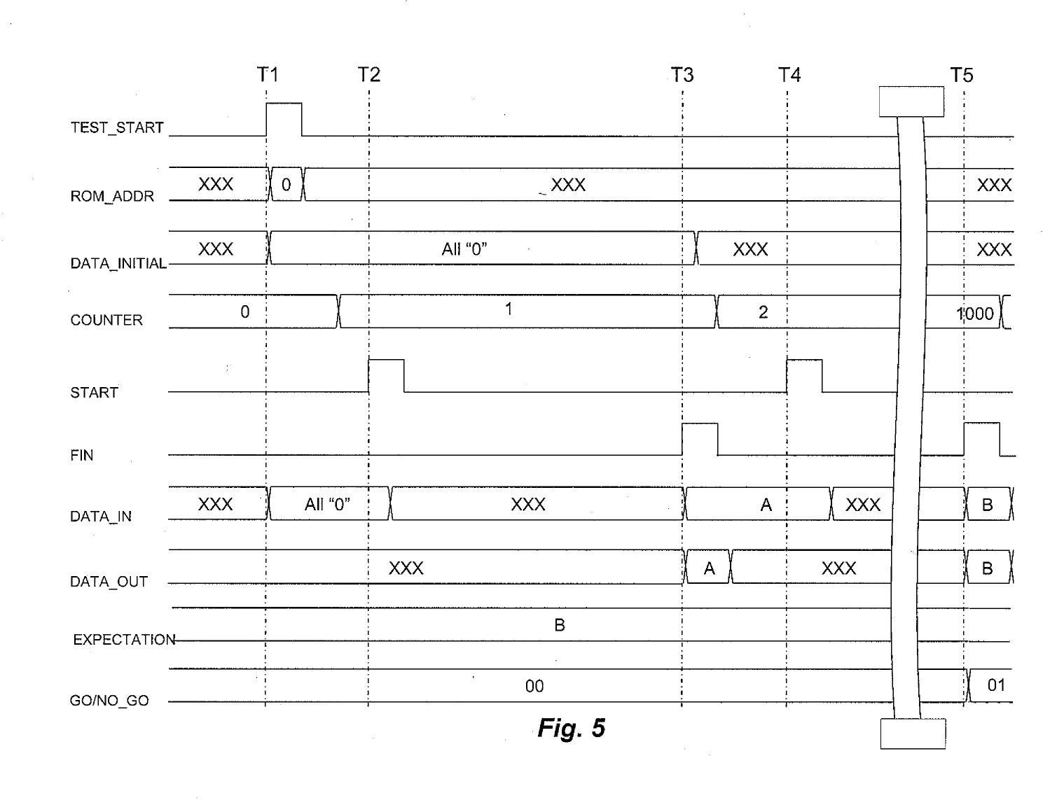

Next, operations of the test circuit 100 and the self-test circuit 200 when a BIST is carried out will be described with reference to FIG. 5. FIG. 5 is a timing diagram for the case where a BIST is carried out.

First, at time T1, a BIST is initiated by a test start signal pulse TEST_START being inputted from outside to the control unit 230. Next, the control unit 230 outputs an address select signal ROM_ADDR“0” to the storage unit 210. With this, the storage unit 210 outputs an initial test pattern DATA_INITIAL “all “0”.” Further, with output of a select signal S2 from the control unit 230 to the multiplexer 250, the multiplexer 250 selects the initial test pattern DATA_INITIAL, and outputs the initial test pattern DATA_INITIAL to the multiplexer 260. Further, with output of a select signal S3 from the control unit 230 to the multiplexer 260, the multiplexer 260 selects the initial test pattern DATA_INITIAL, and outputs the initial test pattern DATA_INITIAL to the test circuit 100 as input data DATA_IN. At this time, the count value of the counter portion 270 is changed from “0” to “1.”

Next, at time T2, for the test circuit 100, a processing (operation) start signal pulse START is asserted. This causes the test circuit 100 to start processing (performing an operation on) the input data DATA_IN.

Next, at time T3 (ten and several clocks after time T2), a signal pulse FIN to stop the operation by the test circuit 100 is asserted, and the test circuit 100 outputs a result of operation as output data DATA_OUT “A.” At this time, the counter portion 270 counts the signal pulse FIN to increment the count value by one (change the count value from “1” to “2”). Further, the feedback unit 220 feeds back the output data DATA_OUT outputted from the test circuit 100, and inputs the output data DATA_OUT to the multiplexer 260. The multiplexer 260 selects the result of operation DATA_OUT to output the result of operation DATA_OUT as input data DATA_IN to the test circuit 100.

Next, at time T4, for the test circuit 100, the processing (operation) start signal pulse START is asserted. This causes the test circuit 100 to start an operation using as input data DATA_IN the output data DATA_OUT, which is a result of operation of the test circuit 100. Thus, a second operation is initiated.

Thereafter, until the count value COUNTER of the counter portion 270 reaches a preset count value (e.g., 1000), the above-described operations (processing (operation) and feedback) are repeated.

Next, at time T5, the comparing unit 240 compares output data DATA_OUT “B” that is outputted from the test circuit 100 when the count value COUNTER of the counter portion 270 coincides with the count value preset in the control unit 230, and the expected value EXPECTATION stored in the storage unit 210. In the case where the result of comparison by the comparing unit 240 indicates that the output data DATA_OUT coincides with the expected value EXPECTATION, the comparing unit 240 outputs “01” as an output signal GO/NO_GO. In the case where the result of comparison by the comparing unit 240 indicates that the calculation result DATA_OUT does not coincide with the expected value EXPECTATION, the comparing unit 240 outputs “11” as an output signal GO/NO_GO.

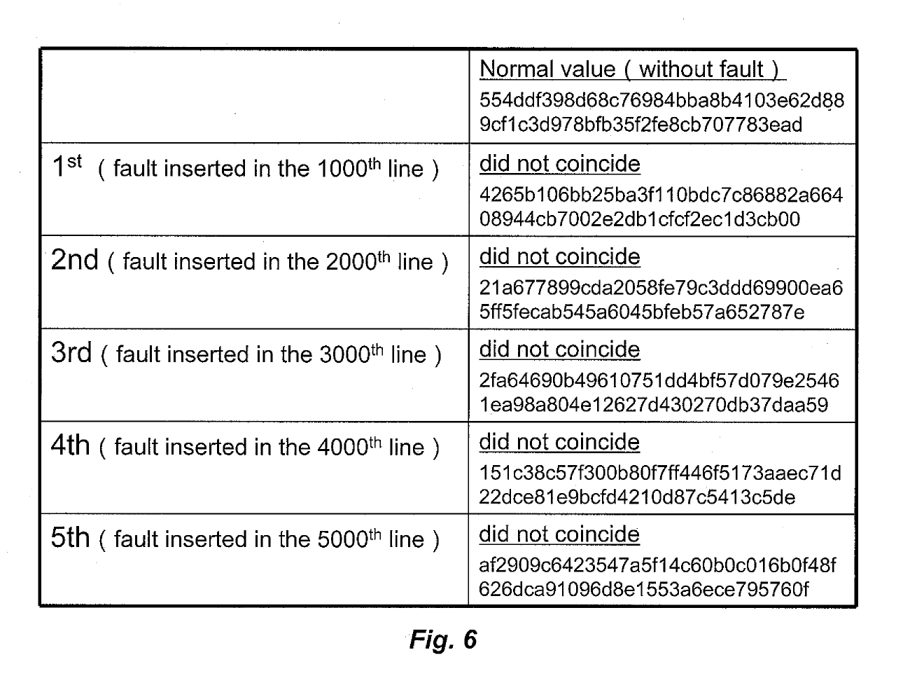

Next, results of carrying out a BIST in the integrated circuit of this embodiment are described with reference to FIG. 6. FIG. 6 is a table showing results of performing a BIST on a gate net of the integrated circuit of this embodiment by simulation.

A BIST was carried out by simulation on a gate net of a semiconductor integrated circuit configured as a test circuit using an SHA (Secure Hash Algorithm) which is generated as a gate net of 65 nm CMOS technology by logical synthesis. A BIST was carried out by simulation on this gate net with a stuck-at-0 or 1 fault being arbitrarily inserted in a primitive cell or a connected signal in an arbitrary row randomly selected. Here, all bits of the initial value of a 512-bit input were “0,” and the number of times of feedback was 1000.

As shown in FIG. 6, the result of operation outputted from each test circuit having a fault inserted in the 1000th, 2000th, 3000th, 4000th, or 5000th line thereof after 1000 times of feedback provided to the circuit, did not coincide with a result of operation after 1000 times of feedback which was outputted from a test circuit (normal circuit) having no fault. As described above, it can be seen that in the semiconductor integrated circuit of this embodiment, a fault arbitrarily inserted in a test circuit was able to be detected. It should be noted that although in the embodiment, 1000 is taken as an example of the number of times of feedback, a fault can be detected even in the case where the number of times of feedback is 1000 or less. However, since fault coverage depends on the randomness of input data inputted to a test circuit, fault coverage increases with an increase in the number of times of feedback.

As described above, in the semiconductor integrated circuit of this embodiment, by the test circuit 100 and the self-test circuit 200 repeating processing (operation) and a feedback action, input data inputted to the test circuit 100 can be made to have high randomness. Accordingly, less random simple data can be used as initial input data DATA_INITIAL, and the initial input data DATA_INITIAL can be stored in the storage unit 210 of small circuit size.

### Second Embodiment

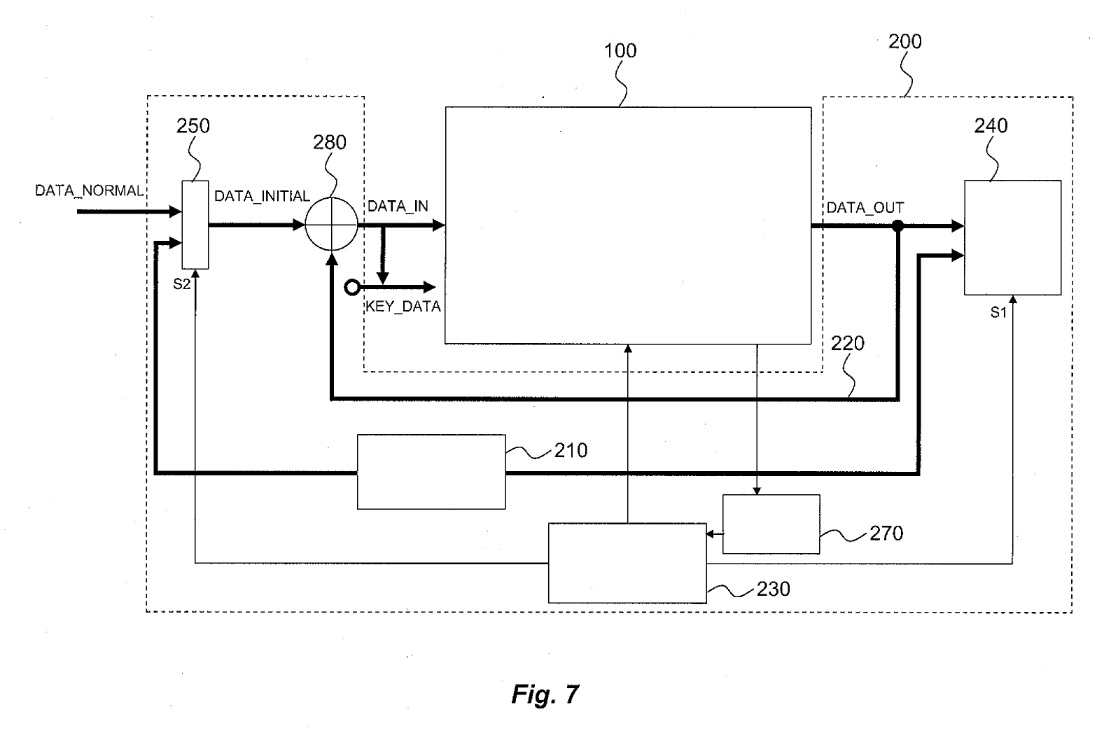

Next, the configuration of a test circuit and a self-test circuit included in a semiconductor integrated circuit according to a second embodiment of the present invention will be described with reference to FIG. 7. FIG. 7 is a block diagram showing the configuration of the test circuit and the self-test circuit included in the semiconductor integrated circuit according to the second embodiment of the present invention. In FIG. 7, components identical or equivalent to those shown in FIG. 2 are denoted by the same reference numerals.

This embodiment differs from the first embodiment in terms of configuration in that an SHA-256 cryptographic core is used as the test circuit 100, and that the multiplexer 260 in FIG. 2 is replaced with an exclusive OR operation circuit 280. Moreover, in response to the test circuit 100 being an SHA-256 cryptographic core, less random simple 512-bit data is used as initial input data DATA_INITIAL.

An SHA-256 cryptographic core encrypts and compresses 512-bit input data DATA_IN to output 256-bit output data DATA_OUT.

In the second embodiment, the exclusive OR operation circuit 280 performs an operation on the 256-bit output data DATA_OUT outputted from the test circuit (SHA-256 cryptographic core) and the 512-bit initial input data DATA_INITIAL outputted from the multiplexer 250. The exclusive OR operation circuit 280 performs exclusive OR operations between the upper 128 bits of the initial input data DATA_INITIAL and the upper 128 bits of the output data DATA_OUT, between the upper 64 bits of the next 128 bits of the initial input data DATA_INITIAL and the next 64 bits of the output data DATA_OUT, between the upper 32 bits of the next 128 bits of the initial input data DATA_INITIAL and the next 32 bits of the output data DATA_OUT, between the upper 32 bits of the next 128 bits of the initial input data DATA_INITIAL and the next 32 bits of the output data DATA_OUT, respectively. The exclusive OR operation circuit 280 outputs an exclusive OR operation result as input data DATA_IN of the test circuit 100.

The use of the exclusive OR operation circuit 280 enables output data to be fed back as input data to the test circuit 100 in the case where data outputted from the test circuit 100 is compressed such as in the case of using an SHA-256 cryptographic core.

It should be noted that the above-described embodiments are intended to facilitate understanding of the present invention and not intended to construe the present invention as limited thereto. The present invention can be changed/modified without departing from the spirit thereof, and the present invention includes equivalents thereto.

What is claimed is:

1. A semiconductor integrated circuit, comprising:
a test module configured to process input data and to output data having higher randomness than the input data; and
a self-test module comprising:
a storage module configured to store initial input data, wherein the initial input data is inputted to the test module when a self-test operation is performed on the test module;
a feedback module configured to feed back, as input data to the test module, the output data from the test module;
a controller configured to control the number of times that the feedback module feeds back the output data from the test module as input data to the test module; and
a comparator configured to compare the output data from the test module with an expected value.

2. The semiconductor integrated circuit of claim 1, wherein the test module comprises a cryptographic core.

3. The semiconductor integrated circuit of claim 2, wherein the storage module comprises a ROM, wherein the ROM comprises one or more combinational circuits.

4. The semiconductor integrated circuit of claim 3, wherein the initial input data comprises any one of n-bit all-zero data or n-bit all-one data, wherein n is a multiple of 256.

5. The semiconductor integrated circuit of claim 4, wherein:
the self-test module further comprises a counter configured to count the number of times that the feedback module feeds back the output data from the test module as input data to the test module, and
the controller module is configured to control, based on the counter, the number of times that the feedback module feeds back the output data from the test module as input data to the test module.

6. The semiconductor integrated circuit of claim 1, wherein:
the self-test module further comprises a counter configured to count the number of times that the feedback module feeds back the output data from the test module as input data to the test module, and
the controller is configured to control, based on the counter, the number of times that the feedback module feeds back the output data from the test module as input data to the test module.

7. The semiconductor integrated circuit of claim 5, wherein the feedback module is further configured to feed back the output data from the test module to a cryptographic key data input of the test module.

8. The semiconductor integrated circuit of claim 1, wherein the feedback module is further configured to feed back the output data from the test module to a cryptographic key data input of the test module.

9. The semiconductor integrated circuit of claim 5, further comprising:
an exclusive-OR module configured to perform an exclusive-OR operation on the output data from the test module, which is fed back through the feedback module, and the initial input data outputted from the storage module, wherein the exclusive-OR module is further configured to output the result of the exclusive-OR operation as input data to the test module,
wherein the test module is configured to compress the input data.

10. The semiconductor integrated circuit of claim 1, further comprising:
an exclusive-OR module configured to perform an exclusive-OR operation on the output data from the test module, which is fed back through the feedback module, and the initial input data outputted from the storage module, wherein the exclusive-OR module is further configured to output the result of the exclusive-OR operation as input data to the test module, wherein the test module is configured to compress the input data.
